(19) United States
(12) Patent Application Publication
(10) Pub. No.: US 2012/0085284 A1
(43) Pub. Date: Apr. 12, 2012

(54) MECHANICALLY FLUIDIZED REACTOR SYSTEMS AND METHODS, SUITABLE FOR PRODUCTION OF SILICON

(76) Inventor: Mark W. Dassel, Indianola, WA (US)

(21) Appl. No.: 13/247,354

(22) Filed: Sep. 28, 2011

Related U.S. Application Data
(60) Provisional application No. 61/390,977, filed on Oct. 7, 2010.

(51) Int. Cl. C23C 16/458

(52) U.S. Cl. 118/716

(57) ABSTRACT

Mechanically fluidized systems and processes allow for efficient, cost-effective production of silicon. Particulate may be provided to a heated tray or pan, which is oscillated or vibrated to provide a reaction surface. The particulate migrates downward in the tray or pan and the reactant product migrates upward in the tray or pan as the reactant product reaches a desired state. Exhausted gases may be recycled.

### CROSS REFERENCE TO RELATED APPLICATION

This application claims benefit under 35 U.S.C. 119(e) of U.S. Provisional Patent Application Ser. No. 61/390,977, filed Oct. 7, 2010, which is incorporated herein by reference in its entirety.

### TECHNICAL FIELD

This disclosure generally relates to mechanically fluidized reactors, which may be suitable for the production of silicon, e.g., polysilicon, for example via chemical vapor deposition.

### BACKGROUND

Silicon, specifically polysilicon, is a basic material from which a large variety of semiconductor product are made. Silicon forms the foundation of many integrated circuit technologies, as well as photovoltaic transducers. Of particular industry interest is high purity silicon.

Processes for producing polysilicon may be carried out in different types of reaction devices, including chemical vapor deposition reactors and fluidized bed reactors. Various aspects of the chemical vapor deposition (CVD) process, in particular the Siemens or “hot wire” process, have been described, for example in a variety of U.S. patents or published applications (see, e.g., U.S. Pat. Nos. 3,011,877; 3,099,534; 3,147,141; 4,150,168; 4,179,530; 4,311,545; and 5,118,485).

Silane and trichlorosilane are both used as feed materials for the production of polysilicon. Silane is more readily available as a high purity feedstock because it is easier to purify than trichlorosilane. Production of trichlorosilane introduces boron and phosphorus impurities, which are difficult to remove because they tend to have boiling points that are close to the boiling point of trichlorosilane itself. Although both silane and trichlorosilane are used as feedstock in Siemens-type chemical vapor deposition reactors, trichlorosilane is more commonly used in such reactors. Silane, on the other hand, is a more commonly used feedstock for production of polysilicon in fluidized bed reactors.

Silane has drawbacks when used as a feedstock for either chemical vapor deposition or fluidized bed reactors. Producing polysilicon from silane in a Siemens-type chemical vapor deposition reactor may require up to twice the electrical energy compared to producing polysilicon from trichlorosilane in such a reactor. Further, the capital costs are high because a Siemens-type chemical vapor deposition reactor yields only about half as much polysilicon from silane as from trichlorosilane. Thus, any advantages resulting from higher purity of silane are offset by higher capital and operating costs in producing polysilicon from silane in a Siemens-type chemical vapor deposition reactor. This has led to the common use of trichlorosilane as feed material for production of polysilicon in such reactors.

Silane as feedstock for production of polysilicon in a fluidized bed reactor has advantages regarding electrical energy usage compared to production in Siemens-type chemical vapor deposition reactors. However, there are disadvantages that offset the operating cost advantages. In using the fluidized bed reactor, the process itself may result in a lower quality polysilicon product even though the purity of the feedstock is high. For example, polysilicon dust may be formed, which may interfere with operation by forming particulate material within the reactor and may also decrease the overall yield. Further, polysilicon produced in a fluidized bed reactor may contain residual hydrogen gas, which must be removed by subsequent processing. In addition, polysilicon produced in a fluidized bed reactor may also include metal impurities due to abrasive conditions within the fluidized bed. Thus, although high purity silane may be readily available, its use as a feedstock for the production of polysilicon in either type of reactor may be limited by the disadvantages noted.

Chemical vapor deposition reactors may be used to convert a first chemical species, present in vapor or gaseous form, to solid material. The deposition may and commonly does involve the chemical conversion of the first chemical species to one or more second chemical species, one of which second chemical species is a substantially non-volatile species.

Chemical deposition is induced by heating the substrate to a certain high temperature at which temperature the first chemical species breaks down on contact into one or more of the aforementioned second chemical species, one of which second chemical species is a substantially non-volatile species. Solids so formed and deposited may be in the form of successive annular layers deposited on bulk forms, such as immobile rods, or deposited on mobile substrates, such as beads or other particulate.

Beads are currently produced, or grown, in a fluid bed reactor where an accumulation of dust, comprised of the desired product of the decomposition reaction, acting as seeds for additional growth, and pre-formed beads, also comprised of the desired product of the decomposition reaction, are suspended, or fluidized, by a gas stream comprised of the first chemical species and commonly of a third non-reactive gas chemical species, and where the dust and beads act as the substrate onto which one of the second chemical species is deposited.

In this system, the third non-reactive chemical specie fulfills two key functions. First, the third non-reactive species acts as a diluent to control the rate of decomposition so that excessive dust, a potential yield loss, is not formed in the decomposition reactor. In this role, the third non-reactive specie is commonly substantially the prevalent species. Second, third non-reactive specie is the means by which the bed of dust and beads is fluidized. To perform this secondary role requires a large volumetric rate of third non-reactive gas specie. The large volumetric flow rate results in high energy costs and creates issues with excessive dust generation—due to abrasive forces inside the fluidized bed, and yield loss—due to blowing dust out of the bed.

### BRIEF SUMMARY

As taught herein, dust, beads or other particulate are mechanically suspended or fluidized, and thereby exposed to the first chemical species, obviating the requirement for a fluidizing gas stream. Mechanical suspension, or fluidization, acts to expose the particulate to the first chemical species by means of repetitive momentum transfer in an oscillating vertical and/or horizontal direction, and/or by mechanical lifting devices. The momentum transfer is produced by mechanical vibration, whereby dust, beads and/or other particulate are heated and brought into contact with the first chemical species. A second chemical species produced by the decomposition of the first chemical species deposits on the dust, beads or other particulate so suspended or fluidized. The dust is thus converted into larger particulate or beads. Dust for use as seeding material may be created from the beads by controlled abrasion, and/or may added to the system from a discrete source of dust, beads or other particulate.

A chemical vapor deposition reactor system may be summarized as including a mechanical means for substantially exposing a surface of a plurality of the dust, beads or other particulate to a gas containing a first gaseous chemical species, a means for heating the dust, beads or other particulate or the surfaces of the dust, beads or other particulate to a sufficiently high temperature such that a first gaseous chemical species brought into contact with said surfaces will chemically decompose and substantially deposit a second chemical species onto said surfaces, and a source of a first gas selected from those chemical species which decompose on heating to one or more second chemical species, one of which is a substantially non-volatile species and prone to deposit on a hot surface in near proximity. The first chemical species may be silane gas (SiH4). The first chemical species may be trichlorosilane gas (SiHCl3). The first chemical species may be dichlorosilane gas (SiH2C12). The mechanical means may be a vibrating bed. The vibrating bed may include at least one of an eccentric flywheel, piezoelectric transducer or sonic transducer. A frequency of vibration may range between 1 and 4,000 cycles per minute. A frequency of vibration may range between 500 and 3,500 cycles per minute. A frequency of vibration may range between 1,000 and 3,000 cycles per minute. A frequency of vibration may be 2,500 cycles per second. An amplitude of the vibration may range between 1/100 inch and 4 inches. The amplitude of vibration may be between 1/100 inch and ½ inch. An amplitude of the vibration may range between 1/64 inch and ¼ inch. An amplitude of the vibration may range between 1/32 inch and ⅛ inch. An amplitude of the vibration may be 1/64 inch.

The reactor system may further include a containment vessel having an interior and an exterior, wherein at least a portion of the mechanical means includes a vibrating bed located in the interior of the containment vessel. Means for heating may be at least partially located in the interior of the containment vessel. The interior of the containment vessel may be filled with a gas containing the first reactant and the third non-reactive specie. The containment vessel may include at least one wall, and the at least one wall may be kept cool by means of a cooling jacket or air cooling fins located on the outside of the containment vessel. A cooling medium may flow through the cooling jacket and may have a temperature and a flow rate controlled so that a temperature of the gas in the interior of the containment vessel may be controlled at a desired low temperature. The bulk temperature of the gas in the interior of the containment vessel may be controlled between 30 C and 500 C. The bulk temperature of the gas in the interior of the containment vessel may be controlled between 50 C and 300 C. The bulk temperature of the gas in the interior of the containment vessel may be controlled at 100 C. The bulk temperature of the gas in the interior of the containment vessel may be controlled at 50 C.

The vibrating bed may include a flat pan with at least one perimeter wall extending therefrom. The vibrating bed may include a bottom surface that may be flat surface and may be heated. The bottom and the at least one perimeter wall may form a container and the dust, beads or other particulate of a second specie and may be placed within the container. A surface temperature of the heated portion of the bed may be controlled to be between 100° C. and 1300° C. A surface temperature of the heated portion of the bed may be controlled to be between 100° C. and 900° C. A surface temperature of the heated portion of the bed may be controlled to be between 200° C. and 700° C. A surface temperature of the heated portion of the bed may be controlled to be between 300° C. and 600° C. A surface temperature of the heated portion of the bed may be controlled to be approximately 450° C. A rate of decomposition of the first specie may be controlled by controlling the surface temperature.

The size of the beads produced may be controlled by a height of the perimeter wall of the container. Larger beads may be formed by increasing the height of the perimeter wall, and smaller beads may be formed by lowering the height of the perimeter wall. The bed may be heated electrically.

A pressure of the gas in the interior of the containment vessel may be controlled to be between 7 psig and 200 psig.

The gas in the interior of the containment vessel may include the first reactant and a third non-reactive specie may be added to the containment vessel, and gas may be comprised of first reactant, third non-reactive diluent, and one of the second species formed by the decomposition reaction may be withdrawn from the containment vessel. Gas including the first reactant and third non-reactive specie may be added continuously to the containment vessel, and gas comprised of first reactant, third non-reactive diluent, and one of the second species formed by the decomposition reaction may be continuously withdrawn from the containment vessel. A degree of conversion of the first reactant may be monitored continuously by sampling the vapor space inside the containment vessel. Gas including the first reactant and third non-reactive specie may be added batch-wise to the containment vessel, and gas comprised of first reactant, third non-reactive diluent, and one of the second species formed by the decomposition reaction may be withdrawn batch-wise from the containment vessel. A degree of conversion of the first reactant may be monitored continuously by sampling the vapor space inside the containment vessel, and/or by monitoring pressure build-up or decrease in the containment vessel. The gas added to the containment vessel may be comprised of silane gas (SiH4) and hydrogen diluent, the gas withdrawn from the containment vessel may be comprised of unreacted silane gas, hydrogen diluent, and hydrogen gas formed by the decomposition reaction, and the dust and beads added to the bed may be comprised of silicon. A decomposition of silane gas may produce polysilicon which deposits on the dust forming beads, and on the beads forming larger beads.

Beads may be continuously harvested from the bed, and the average size of the harvested beads may be controlled by adjusting a height of the perimeter wall the container. Larger size beads may be formed by increasing a height of the perimeter wall of the container, and smaller beads may be formed by lowering the height of the perimeter wall of the container. An average bead size may be controlled between 1/100 inch diameter and ¼ inch diameter. An average bead size may be controlled between 1/64 inch diameter and 3/16 inch diameter. An average bead size may be controlled between 1/32 inch diameter and ⅛ inch diameter. An average bead size may be controlled at ⅛ inch diameter.

A pressure of the gas within the containment vessel may be controlled between 5 psia and 300 psia. A pressure of the gas within the containment vessel may be controlled between 14.7 psia and 200 psia. A pressure of the gas within the containment vessel may be controlled between 30 psia and 100 psia. A pressure of the gas within the containment vessel may be controlled at 70 psia. A pressure of the gas within the containment vessel at the beginning of the batch reaction may be controlled at 14.7 psia, and at the end of the batch reaction at 28 psia to 32 psia.

The first chemical specie conversion may be controlled by adjusting the temperature of the bed, the frequency of vibration, the vibration amplitude, a concentration of the first species in the reaction or containment vessel, a pressure of the gas (e.g., first species and diluent) in the reaction or containment vessel and the hold-up time of the gas within the containment vessel. Silane conversion may be controlled by adjusting the temperature of the bed, the frequency of vibration, the vibration amplitude, and the hold-up time of the gas within the containment vessel. The silane gas conversion may be controlled between 20% and 100%. The silane gas conversion may be controlled between 40% and 100%. The silane gas conversion may be controlled between 80% and 100%. The silane gas conversion may be controlled at 98%.

A height of the perimeter wall may be between ¼ inch and 15 inches. A height of the perimeter wall may be between ½ inch and 15 inches. A height of the perimeter wall may be between ½ inch and 5 inches. A height of the perimeter wall may be between ½ inch and 3 inches. A height of the perimeter wall may be approximately 2 inches.

The electric heating may be performed by a resistive heating coil located beneath the surface of the pan. The resistive heating coil may be located within a sealed container. The sealed container may be insulated on all sides except for the side in direct contact with the underside of the pan. An underside of the pan may form the top side of the sealed container holding the heating coil.

The mechanical means for substantially exposing the surface of the plurality of beads to a gas containing a first gaseous chemical species and diluent gas and the means for heating the beads or the surfaces of the beads may be made from metal or graphite or a combination of metal and graphite. The metal may be 316 SS or nickel.

A formation rate of the beads may be matched to a formation rate of dust. The formation rate of dust may be controlled by adjusting the frequency of vibration, the vibration amplitude, and the height of the sides.

The hydrogen withdrawn from the containment vessel may be recovered for use in associated silane production processes or for sale. A residual concentration of hydrogen gas entrained with the beads or incorporated into the second chemical specie comprising the beads may be controlled by controlling the concentration of the hydrogen diluent in the gas added to the containment vessel. The concentration of the hydrogen diluent may be controlled between 0 and 90 mole percent. The concentration of the hydrogen diluent may be controlled between 0 and 80 mole percent. The concentration of the hydrogen diluent may be controlled between 0 and 90 mole percent. The concentration of the hydrogen diluent may be controlled between 0 and 50 mole percent. The concentration of the hydrogen diluent may be controlled between 0 and 20 mole percent.

Beads overflowing from the pan may be removed from the bottom of the containment vessel through a lock hopper mechanism comprised of two or more isolation valves and an intermediate second containment vessel.

### BRIEF DESCRIPTION OF SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements, as drawn, are not intended to convey any information regarding the actual shape of the particular elements, and have been solely selected for ease of recognition in the drawings.

FIG. 1 is a partially broken schematic view of a system including a pressurized containment vessel, a mechanically fluidized bed located in the containment vessel, and various supply lines and output lines, useful in the preparation of silicon, according to one illustrated embodiment.

FIG. 2 is an isometric diagram of a mechanically fluidized bed mechanically oscillated or vibrated via a rotating elliptical bearing or cam(s), according to one illustrated embodiment.

FIG. 3 is a cross-section view of a mechanically fluidized bed mechanically oscillated or vibrated via a number of piezoelectric transducers, according to another illustrated embodiment.

FIG. 4 is a cross-section view of a mechanically fluidized bed mechanically oscillated or vibrated via a number of ultrasonic transducers, according to another illustrated embodiment.

### DETAILED DESCRIPTION

In the following description, certain specific details are included to provide a thorough understanding of various disclosed embodiments. One skilled in the relevant art, however, will recognize that embodiments may be practiced without one or more of these specific details, or with other methods, components, materials, etc. In other instances, well-known structures associated with systems for making silicon including, but not limited to, interior structures of mixers, separators, vaporizers, valves, controllers, and/or recombination reactors, have not been shown or described in detail to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is, as “including, but not limited to.”

Reference throughout this specification to “one embodiment,” or “an embodiment,” or “another embodiment,” or “some embodiments,” or “certain embodiments” means that a particular referent feature, structure, or characteristic described in connection with the embodiment is included in at least one embodiment. Thus, the appearance of the phrases “in one embodiment,” or “in an embodiment,” or “in another embodiment,” or “in some embodiments,” or “in certain embodiments” in various places throughout this specification are not necessarily all referring to the same embodiment. Furthermore, the particular features, structures, or characteristics may be combined in any suitable manner in one or more embodiments.

It should be noted that, as used in this specification and the appended claims, the singular forms “a,” “an,” and “the” include plural referents unless the content clearly dictates otherwise. Thus, for example, reference to a chlorosilane includes a single species of chlorosilane, but may also include multiple species of chlorosilanes. It should also be noted that the term “or” is generally employed as including “and/or” unless the content clearly dictates otherwise.

As used herein, the term “silane” refers to SiH₄. As used herein, the term “silanes” is used generically to refer to silane and/or any derivatives thereof. As used herein, the term “chlorosilane” refers to a silane derivative wherein one or more of hydrogen has been substituted by chlorine. The term “chlorosilanes” refers to one or more species of chlorosilane. Chlorosilanes are exemplified by monochlorosilane (SiH₃Cl or MCS); dichlorosilane (SiH₂Cl₂ or DCS); trichlorosilane (SiHCl₃ or TCS); or tetrachlorosilane, also referred to as silicon tetrachloride (SiCl₄ or STC). The melting point and boiling point of silanes increases with the number of chlorines in the molecule. Thus, for example, silane is a gas at standard temperature and pressure, while silicon tetrachloride is a liquid.

As used herein, unless specified otherwise, the term “chlorine” refers to atomic chlorine, i.e., chlorine having the formula Cl, not molecular chlorine, i.e., chlorine having the formula Cl₂. As used herein, the term “silicon” refers to atomic silicon, i.e., silicon having the formula Si.

As used herein, the term “chemical vapor deposition reactor” or “CVD reactor” refers to a Siemens-type or “hot wire” reactor.

Unless otherwise specified, the terms “silicon” and “polysilicon” are used interchangeably herein when referring to the silicon product of the methods and systems disclosed herein.

Unless otherwise specified, concentrations expressed herein as percentages should be understood to mean that the concentrations are in mole percent.

The headings provided herein are for convenience only and do not interpret the scope or meaning of the embodiments.

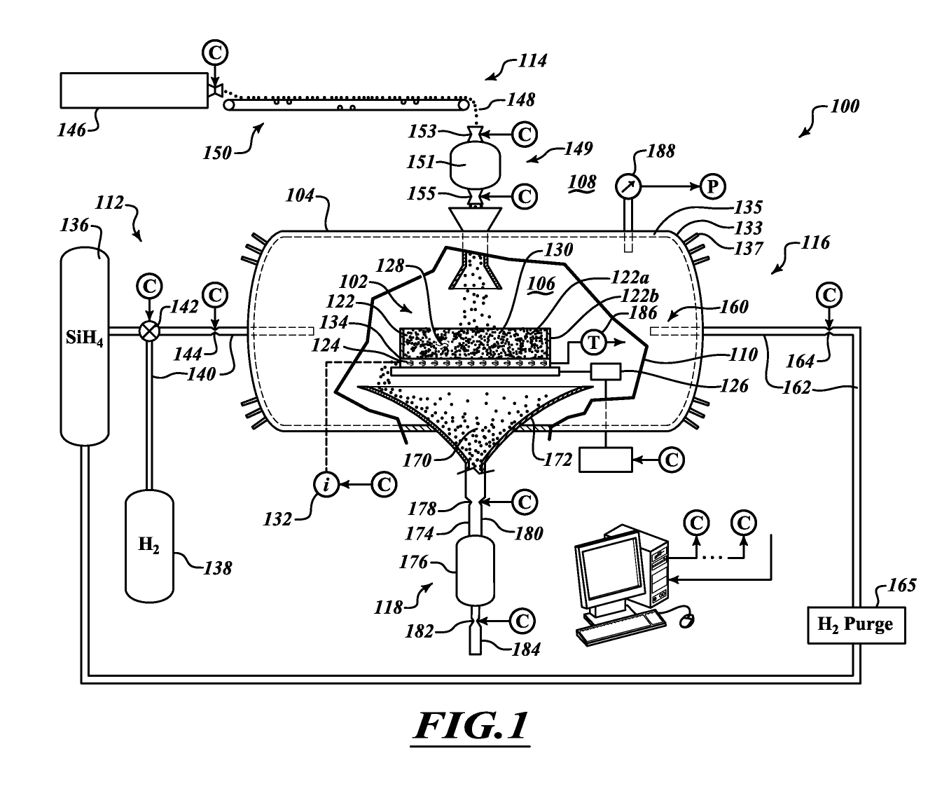

FIG. 1 shows a mechanically fluidized bed reactor system 100, according to one illustrated embodiment.

The mechanically fluidized bed reactor system 100 includes a mechanically fluidized bed apparatus 102 which mechanically fluidizes particulate (e.g., dust, beads), provides heat and upon which the desired reaction(s) are produced. The mechanically fluidized bed reactor system 100 may also include a reaction vessel 104, having an interior 106 separated from an exterior 108 thereof be one or more vessel walls 110. The mechanically fluidized bed apparatus 102 may be positioned in the interior 106 of the reaction vessel 104. The mechanically fluidized bed reactor system 100 includes a reactant gas supply subsystem 112, particulate supply subsystem 114, an exhaust gas recovery subsystem 116, and a reacted product collection subsystem 118 to collect the desired product of the reaction. The mechanically fluidized bed reactor system 100 may further include an automated control subsystem 120, coupled to control various other structures or elements of the mechanically fluidized bed reactor system 100. Each of these structures or subsystems are discussed below, in turn.

The mechanically fluidized bed apparatus 102 includes at least one tray or pan 122 having a bottom surface 122a, at least one heating element 124 (only one called out in FIG. 1) thermally coupled to heat at least the bottom surface 122a of the tray or pan 122, and an oscillator 126 coupled to oscillate or vibrate the at least the bottom surface 122a of the tray 122. The tray 122 may also include a perimeter wall 122b, extending generally perpendicular from the bottom surface 122a of the tray 122. The perimeter wall 122b and bottom surface 122a form a recess 128 with may temporarily retain material 130 being subjected to a desired reaction. The bottom surface 122a, and possible the perimeter wall 122b, should be formed of a material that does not become quickly impaired by a buildup of reactant product. The bottom surface 122a, and/or the tray 122, may be formed of metal or graphite or a combination of metal and graphite. The metal may, for example, take the form of 316 SS or nickel. The fluidization of the bed via mechanically induced vibration or oscillation is the mechanism by which a first reactive species is incorporated into the bed and brought into close proximity or intimate contact with the hot dust, beads, or other particulate. The term mechanically fluidized bed as used herein and in the claims means the suspension of fluidization of particulate (e.g., dust, beads or other particulate) via oscillation or vibration whether the oscillation or vibration is coupled to the bed or tray via a mechanical, magnetic, sonic, or other mechanism. Such is distinguished from fluidization caused by gas flow through the particulate. The terms vibration and oscillations, and variations of such (e.g., vibrating, oscillating) are used interchangeably herein and in the claims. Further, the terms tray or pan are used interchangeably herein and in the claims to refer to a structure having a bottom surface and at least one wall extending therefrom to form a recess capable of temporarily retaining the mechanically fluidized bed.

The heating element 124 may take a variety of forms, for example, one or more radiant or resistive elements which produce heat in response to an electrical current being passed therethrough from a current source 132, for instance in response to a control signal. The radiant or resistive element(s) may, for instance, be similar to the electric coils commonly found in electric cook top stoves, or immersion heaters.

The heating element 124 may be enclosed in a sealed container. For example, the radiant or resistive element(s) may be enclosed on all sides. For instance, a thermally insulating material 134 may surround the radiant or resistive element(s) on all sides except for a portion that forms the bottom surface 122a of the tray or pan 122 or which is proximate the bottom surface 122a. The thermally insulating material may, for instance take the form of a glass-ceramic material (e.g., Li₂O×Al₂O₃×nSiO₂-System or LAS System) similar that used in “glass top” stoves where there electrical radiant or resistive heating elements are positioned beneath a glass-ceramic cooking surface. The thermally insulating or insulative material may take forms other than glass-ceramic. As noted above, above an thermal insulator may be used on all sides of the sealed container except the portion that is proximate or which forms the bottom surface 122a of the tray or pan 122. The heat transfer mechanism may be conduction, radiant or a combination of such.

As discussed below, as product reacts, the mass and/or volume of individual pieces 130 may increase. Unexpectedly, larger pieces migrate upward in the tray or pan 122, while the smaller pieces migrate downward. Once particles 130 reach a desired size, the particles 130 may vibrate over the perimeter wall 122b, falling generally downward in the reaction vessel 104.

The interior 106 of the reaction vessel 104 may be raised to or maintained at an elevated pressure relative to the exterior 108 thereof. Thus the vessel wall 110 should be of suitable material and thickness to withstand the expected working pressures to which the vessel wall 110 will be subjected. Additionally, the overall shape of the reaction vessel 104 may be selected or designed to withstand such expected working pressures. Further, reaction vessel 104 should be designed to withstand repeated pressurization cycles with an adequate safety margin.

The reactant vessel 104 may include a cooling jacket 133 with suitable coolant fluid 135 pumped therein. Additionally, or alternatively, the reactant vessel may include cooling fins 137 (only one called out in FIG. 1) or other cooling structures which provide a large surface area for heat dissipation into the exterior 108.

The reactant gas supply system 112 may be coupled to supply a reactant gas to the interior 106 of the reaction vessel 104. The reactant gas supply system 112 may, for example, include a reservoir of silane 136. The reactant gas supply system 112 may also include a reservoir of hydrogen 138. While illustrated as separate reservoirs, some embodiments may employ a combined reservoir for the silane and hydrogen. The reactant gas supply system 112 may also include one or more conduits 140, mixing valves 142, flow regulating valves 144, and other components (e.g., blowers, compressors) operable to provide silane and hydrogen into the interior 106 of the reaction vessel 104. Various elements of the reactant gas supply system 112 may be manually or automatically controlled, as indicated by control arrows (i.e., single headed arrows with© located at tails). In particular, a ratio of diluent (e.g., hydrogen) to reactant or first species (e.g., silane) is controlled.

The particulate supply subsystem 114 may supply particulate to the interior 106 of the reaction vessel 104, as needed. The particulate supply subsystem 114 may include a reservoir 146 of particulate 148. The particulate supply subsystem 114 may include an input lock hopper 149, operable to control a delivery or supply of the particulate 148 from the particulate reservoir 146 to the recess 128 of the tray or pan 122 in the interior 106 of the reaction vessel 104. The input lock hopper 149 may, for example, include an intermediate containment vessel 151, an inlet valve 153 operable to selectively seal an inlet of the intermediate containment vessel 151 and an outlet valve 155 operable to selectively seal and outlet of the intermediate containment vessel 151. The particulate supply subsystem 114 may additionally, or alternatively, include a conveyance subsystem 150 to deliver the particulate 148 from the particulate reservoir 146 to the recess 128 of the tray or pan 122 in the interior 106 of the reaction vessel 104 or to the input lock hopper 149. In some embodiments, the intermediate containment vessel 151 of the input lock hopper may serve as the reservoir of particulate. In any case, the amount of particulate provided to the interior 106 of the reactor or containment vessel 104 may be automatically or manually control. The conveyance subsystem 150 can take a variety of forms. For example, the conveyance subsystem 150 may include one or more conduits and blowers. The blowers may be selectively operated to drive a desired amount of particulate 148 to the interior of the reaction vessel 104. Alternatively, the conveyance subsystem 150 may include a conveyor belt with suitable drive mechanism such as an electric motor and a transmission such as gears, clutch, pulleys, and or drive belt. Alternatively, the conveyance subsystem 150 may include an auger or other transport mechanism. The particulate may take a variety of forms. For example, the particulate may be provided as dust or beads, which serve as a seed for the desired reaction. Once seeded, the mechanical oscillation or vibration of the tray or pan 122 may create additional dust, and may become, at least to some degree, self seeding.

The exhaust gas recovery subsystem 116 includes an inlet 160 fluidly coupled with the interior 106 of the reaction vessel 104. The exhaust gas recovery subsystem 116 may include one or more conduits 162, flow regulating valves 164, and other components (e.g., blowers, compressors) recover exhaust gas from the interior 106 of the reaction vessel 104. One or more of the components of the exhaust gas recovery subsystem 116 may be manually or automatically controlled, as indicate by control signals (single headed arrow with© positioned at tail). The exhaust gas recovery subsystem 116 may return recovered exhaust gas to the reservoir(s) of the reactant gas supply system 112. The exhaust gas recovery subsystem 116 may return the recovered exhaust gas directly to the reservoir(s) without any treatment, or may return the recovered exhaust gas after suitable treatment. For example, the exhaust gas recovery subsystem 116 may include a purge subsystem 165. The purge subsystem 165 may purge some or all of the second species (e.g., hydrogen) from the exhaust gas stream. This may be useful because there may be a net production of the second species during the reaction. For example, there may be a net production of hydrogen as saline is decomposed into silicon.

The reacted product collection subsystem 118 collects the desired product of the reaction 170 which falls from the tray or pan 122 of the mechanically fluidized bed apparatus 102. The reacted product collection subsystem 118 may include funnel or chute 172 positioned relatively beneath the tray or pan 122, and extending beyond a perimeter of the tray or pan 122 a sufficient distance to ensure that most of the resulting reaction product 170 is caught. Suitable conduit 174 may fluidly couple the funnel or chute 172 to an output lock hopper 176. An inlet flow regulating valve 178 is manually or automatically operable via (control signals indicated by single headed arrow with© at tail) to selectively couple an inlet 180 of the output lock hopper 176 to the interior 106 of the reaction vessel 104. An outlet flow regulating valve 182 is manually or automatically operable (control signals indicated by single headed arrow with© at tail) to selectively provide reacted product from the output lock hopper 176 via an outlet 184 thereof. An intermediate second containment vessel may be used to collect beads or particulate overflowing from the tray or pan 122.

The control subsystem 120 may be communicatively coupled to control one or more other elements of the 100. The control subsystem 120 may include one or more sensors which produce sensor signals (indicated by single headed arrows, with T in a circle located at the tail) indicative of an operation parameter of one or more components of the mechanically fluidized bed reactor system 100. For instance, the control subsystem 120 may include a temperature sensor (e.g., thermocouple) 186 to produce signals indicative of a temperature, for example signals indicative of a temperature of a bottom surface 122a of the tray or pan 122, or of the contents 130 thereof. Also for instance, the control subsystem 120 may include a pressure sensor 188 to produce sensor signals indicative of a pressure (indicated by single headed arrows, with P in a circle located at the tail). Such pressure signals may, for example, be indicative of a pressure in the interior 106 of the reaction vessel 104. The control subsystem 120 may also receive signals from sensors associated with various valves, blowers, compressors, and other equipment. Such may be indicative of a position or state of the specific pieces of equipment and/or indicative of the operating characteristics within the specific pieces of equipment such as flow rate, temperate, pressure, vibration frequency, density, weight, and/or size.

The control subsystem 120 may use the various sensor signals in automatically controlling one or more of the elements of the mechanically fluidized bed reactor system 100 according to a defined set of instructions or logic. For example, the control subsystem 120 may produce control signals for controlling various elements such as valve(s), heater(s), motors, actuators or transducers, blowers, compressors, etc. Thus, for instance, the control subsystem 120 may be communicatively coupled and configured to control one or more valves, conveyors or other transport mechanisms to selectively provide particulate to the interior of the reaction or containment vessel. Also for instance, the control subsystem 120 may be communicatively coupled and configured to control a frequency of vibration or oscillation of the tray or pan 122 to produce the desired fluidization. The control subsystem 120 may be communicatively coupled and configured to control a temperature of the tray or pan, or contents thereof. Such may be done by controlling a flow of current through radiant or resistive heater element(s). Also for instance, the control subsystem 120 may be communicatively coupled and configured to control a flow of reactant gas into the interior of the reaction or containment vessel. Such may be done by controlling one or more valves, for example via solenoids, relays or other actuators and/or controlling one or more blowers or compressors, for example by controlling a speed of an associated electric motor. Also for instance, the control subsystem 120 may be communicatively coupled and configured to control the withdrawal of exhaust gas from the reaction of containment vessel. Such may be done by providing suitable control signals to control one or more valves, dampers, blowers, exhaust fans, via one or more solenoids, relays, electric motors or other actuators.

The control subsystem 120 may take a variety of forms. For example, the control subsystem 120 may include a programmed general purpose computer having one or more microprocessors and memories (e.g., RAM, ROM, Flash, spinning media). Alternatively, or additionally, the control subsystem 120 may include a programmable gate array, application specific integrated circuit, and/or programmable logic controller.

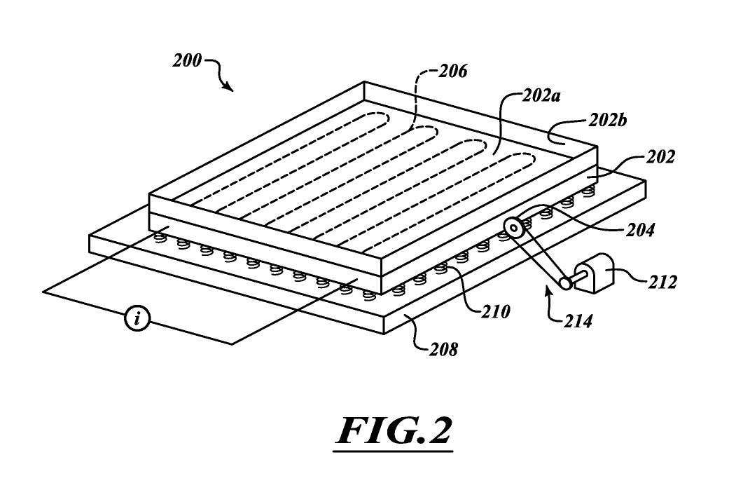

FIG. 2 shows a mechanically fluidized bed 200 including a tray or pan 202 mechanically oscillated or vibrated via a rotating elliptical bearing or one or more cams 204, which cams may be synchronized, according to one illustrated embodiment.

The tray or pan 202 includes a bottom surface 202a and perimeter wall 202b extending perpendicularly thereto to from a recess to temporarily retain the material being subjected to the reaction. A number of heating elements 206 (shown in broken line) pass through the tray or pan 202 and are operable to heat at least the bottom surface 202a, and the contents in contact with the bottom surface 202a.

The tray or pan 202 may be suspended from a base 208 by one or more resilient member 210 (only one called out in FIG. 2). The resilient members 210 allow the tray or pan 202 to oscillate or vibrate in at least one direction or orientation relative to the base 208. The resilient members 210 may, for example, take the form of one or more springs. The resilient members 210 may take the form of a gel, rubber or foam rubber. Alternatively, the tray or pan 202 may be coupled to the base 208 via one or more magnets (e.g., permanent magnets, electromagnets, ferrous elements). In yet a further embodiment, the tray or pan 202 may be suspended from the base 208 via one or more wires, cables, strings, or springs.

The elliptical bearing or cam 204 is driven via an actuator, for example an electric motor 212. The electric motor 212 may be drivingly coupled to the elliptical bearing or cam 204 via a transmission 214. The transmission 214 may take a variety of forms, for example one or more of gears, pulleys, belts, drive shafts, or magnets to physically and/or magnetically couple the electric motor 212 to the elliptical bearing or cam 204. The elliptical bearing or cam 204 successively oscillates the bed or tray 20 as the elliptical bearing or cam 204 rotates.

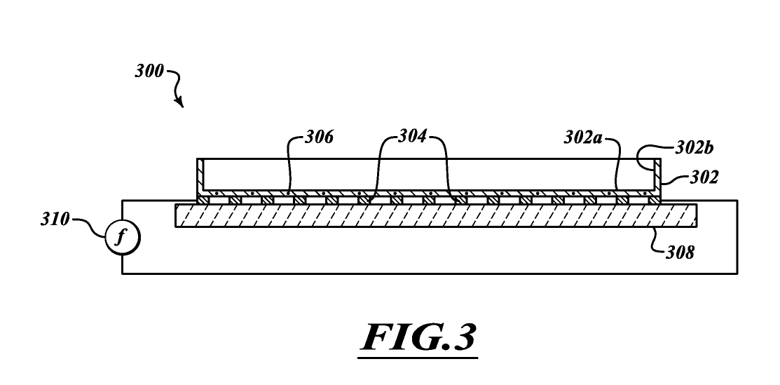

FIG. 3 shows a mechanically fluidized bed 300 including a tray or pan 302 mechanically oscillated or vibrated via a number of piezoelectric transducers or actuators 304 (two called out in FIG. 3), according to another illustrated embodiment.

The tray or pan 302 includes a bottom surface 302a and a perimeter wall 302b extending perpendicularly from a perimeter thereof, to for a recess to retain material therein. A number of heating elements 306 (only one called out in FIG. 3) are thermally coupled to the bottom surface 302a and are operable to heat at least the bottom surface 302a and contents in contact with the bottom surface 302a. As explained above, the heating elements 306 may take the form of radiant elements or electrically resistive elements. Alternatively, other elements may be employed, for example, using lasers or heated fluids.

The tray or pan 302 is coupled to a base 308. In some embodiments the tray or pan 302 is physically coupled to the base 308 only via the piezoelectric transducers 304. In other embodiments, the tray or pan 302 is physically coupled to the base 308 via one or more resilient members (e.g., springs, gels, rubber, foam rubbers). In further embodiments, the tray or pan 302 may be coupled to the base 308 via one or more magnets (e.g., permanent magnets, electromagnets, ferrous elements). In yet a further embodiment, the tray or pan 302 may be suspended from the base 308 via one or more wires, cables, strings, or springs.

A number of piezoelectric transducers 304 are physically coupled to the tray or pan 302. The piezoelectric transducers 304 are electrically coupled to a current source 310 that applies a varying current to cause the piezoelectric transducers 304 to oscillate or vibrate the tray or pan 202 with respect to the base. The electrical current can be controlled to achieve a desired oscillation or vibration frequency.

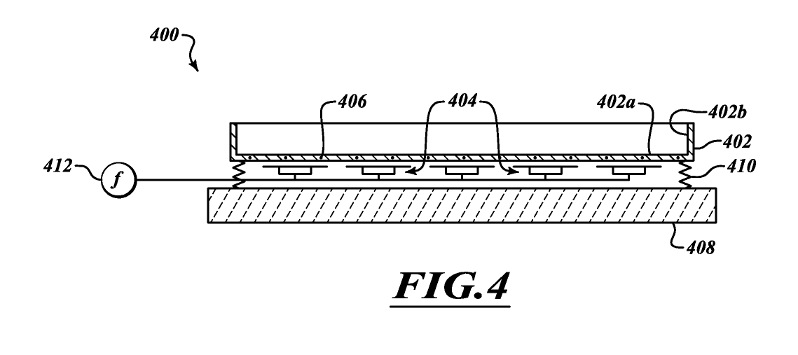

FIG. 4 shows a mechanically fluidized bed 400 including a tray or pan 402 mechanically oscillated or vibrated via a number of ultrasonic transducers or actuators 404 (two called out in FIG. 4), according to another illustrated embodiment.

The tray or pan 402 includes a bottom surface 402a and a perimeter wall 402b extending perpendicularly from a perimeter thereof, to for a recess to retain material therein. A number of heating elements 406 (only one called out in FIG. 4) are thermally coupled to the bottom surface 402a and are operable to heat at least the bottom surface 402a and contents in contact with the bottom surface 402a. As explained above, the heating elements 406 may take the form of radiant elements or electrically resistive elements, and may be covered by an insulation layer (e.g., glass-ceramic). Alternatively, other heating elements may be employed, for example using lasers or heated fluids.

The tray or pan 402 is coupled to a base 408. The tray or pan 402 may be physically coupled to the base 408 only via one or more resilient elements 410 (e.g., springs, gels). Alternatively, the tray or pan 402 may be coupled to the base 408 via one or more magnets (e.g., permanent magnets, electromagnets, ferrous elements). In yet a further embodiment, the tray or pan 402 may be suspended from the base 408 via one or more wires, cables, strings, or springs.

A number of ultrasonic transducers 404 are operable to produce ultrasonic waves and to propagate such ultrasonic pressure waves to the tray or pan 402 or the contents thereof. The piezoelectric transducers 404 are electrically coupled to a current source 412 that applies a varying current to cause the ultrasonic transducers 404 to oscillate or vibrate the tray or pan 402 or contents thereof with respect to the base 408. The electrical current can be controlled to achieve a desired oscillation or vibration frequency.

### EXAMPLE

The first chemical species may take a variety of forms, including silane gas (SiH4); trichlorosilane gas (SiHCl3); or dichlorosilane gas (SiH2C12). Such may be provided in a gaseous form into a reaction or containment vessel 104.

A second chemical specie may take the form of dust, beads or other particulate, and may be located in a recess formed by a tray or pan. A height of a perimeter wall may effectively control the size of beads or other particulate produced. In particular, a taller perimeter wall, with respect to the bottom surface of the tray or pan, will cause the formation of larger beads or other particulate. The height of the perimeter wall may be between ½ inch and 15 inches. A height of between ½ inch and 10 inches; between ½ inch and 5 inches; between ½ inch and 3 inches; or approximately 2 inches may be particularly advantageous.

A third non-reactive specie may be added to the reactant or containment vessel 104. The third non-reactive functions as a diluent.

At least a bottom surface of a tray or pan may be heated. Temperatures in the range of between 100° C. and 900° C.; 200° C. and 700° C.; 300° C. and 600° C.; or approximately at 450° C. may be particularly suitable. The rate of the decomposition of the first specie may be effectively controlled by controlling the temperature of the bottom surface of the tray or pan.

The oscillation or vibration may be along any one or more axis or about any one or more axis. The oscillation or vibration may be at any of a number of frequencies. Particularly advantageous frequencies may include between 1 and 4,000 cycles per minute; between 500 and 3,500 cycles per minute; between 1,000 and 3,000 cycles per minute; or 2,500 cycles per second. Various magnitudes or amplitudes of oscillation or vibration may be employed. An amplitude of between 1/100 inch and ½ inch; between 1/64 inch and ¼ inch; between 1/32 inch and ⅛ inch; or approximately 1/64 inch may be particularly advantageous.

Bulk temperature of the gas in the interior 106 of the reaction or containment vessel 104 may be controlled. A range of between 30° C. and 500° C.; between 50° C. and 300° C.; approximately at 100° C. or approximately at 50° C., may be particularly advantageous.

A pressure of gas within the reaction or containment vessel 104 may be controlled. A pressure between 7 psig and 200 psig may be particularly advantageous. A pressure between 5 psia and 300 psia; between 14.7 psia and 200 psia; 30 psia and 100 psia; approximately 70 psia; may be advantageous. The pressure of the gas within the reaction or containment vessel 104 at the beginning of the batch reaction may be controlled to be approximately 14.7 psia, and at the end of the batch reaction may be approximately 28 psia to 32 psia.

The second species, formed by the decomposition reaction, may be withdrawn from the reaction or containment vessel 104. Such may be withdrawn in batches or continuously. Notably, the low gas density of the second species (e.g., hydrogen) formed in the decomposition of the first species (e.g., silane) relative to the higher density of the first species facilitates the disengagement of the second species from the fluidized bed or particulate. This enables the first species to come into close proximity or intimate contact with the hot dust, beads or other particulate. For instance, hydrogen will tend to rise in the mechanically fluidized bed of particulate, while silane will tend to sink therein.

Silane gas conversion may be between 20% and 100%; between 40% and 100%; 80% and 100%; or approximately 98%.

A control subsystem or an operator may monitor the degree of conversion of the first reactant. For example, the degree of conversion may be monitored continuously by sampling the vapor space inside the reaction or containment vessel 104.

Gas including the first reactant and third non-reactive species may be added batch-wise to the reaction or containment vessel 104. Gas including the first reactant, third non-reactive diluent, and one of the second species formed by the decomposition reaction may be withdrawn batch-wise from the reaction of containment vessel 104. The gas added to the reaction or containment vessel 104 may, for example, include silane gas (SiH4) and hydrogen diluent, and the gas withdrawn from the reaction or containment vessel 104 may include unreacted silane gas, hydrogen diluent, and hydrogen gas formed by the decomposition reaction. The dust, beads or other particulate added to the tray or pan 122 may comprise silicon.

The decomposition of silane gas may produce polysilicon which deposits on the dust forming beads or other particulate, and on the beads forming larger beads or particulate. Beads or other particulate may be continuously harvested from the bed or tray 122. Average bead size produced may be between 1/100 inch diameter and ¼ inch diameter; between 1/64 inch diameter and 3/16 inch diameter; between 1/32 inch diameter and ⅛ inch diameter; or ⅛ inch diameter.

The formation rate of the beads may be matched to the formation rate of dust. The formation rate of dust may be controlled by adjusting the frequency of vibration, the vibration amplitude, and/or the height of the perimeter wall.

Hydrogen withdrawn from the reaction or containment vessel 104 may be recovered for use in associated silane production processes or for sale.

A residual concentration of hydrogen gas entrained with the beads or incorporated into the second chemical specie comprising the beads may be controlled by controlling the concentration of the hydrogen diluent in the gas added to the containment vessel. The concentration of the hydrogen diluent may be between 0 and 90 mole percent; between 0 and 80 mole percent; between 0 and 90 mole percent; between 0 and 50 mole percent; or between 0 and 20 mole percent.

The systems and processes disclosed and discussed herein for the production of silicon may have marked advantages over systems and processes currently employed.

The systems and processes are suitable for the production of either semiconductor grade or solar grade silicon. The use of silane as a starting material in the production process allows high purity silicon to be produced more readily. Silane is much easier to purify. Because of its low boiling point, it can be readily purified and during purification does not have the tendency to carry along contaminants as may occur in the preparation and purification of trichlorosilane as a starting material. Further, certain processes for the production of trichlorosilane utilize carbon or graphite, which may carry along into the product or react with chlorosilanes to form carbon-containing compounds.

The above description of illustrated embodiments, including what is described in the Abstract, is not intended to be exhaustive or to limit the embodiments to the precise forms disclosed. Although specific embodiments and examples are described above for illustrative purposes, various equivalent modifications can be made without departing from the spirit and scope of the disclosure, as will be recognized by those skilled in the relevant art. The teachings provided above of the various embodiments can be applied to other systems, methods and/or processes for producing silicon, not only the exemplary systems, methods and devices generally described above.

For instance, the detailed description above has set forth various embodiments of the systems, processes, methods and/or devices via the use of block diagrams, schematics, flow charts and examples. Insofar as such block diagrams, schematics, flow charts and examples contain one or more functions and/or operations, it will be understood by those skilled in the art that each function and/or operation within such block diagrams, schematics, flowcharts or examples can be implemented, individually and/or collectively, by a wide range of system components, hardware, software, firmware, or virtually any combination thereof.

In certain embodiments, the systems used or devices produced may include fewer structures or components than in the particular embodiments described above. In other embodiments, the systems used or devices produced may include structures or components in addition to those described herein. In further embodiments, the systems used or devices produced may include structures or components that are arranged differently from those described herein. For example, in some embodiments, there may be additional heaters and/or mixers and/or separators in the system to provide effective control of temperature, pressure, or flow rate. Further, in implementation of procedures or methods described herein, there may be fewer operations, additional operations, or the operations may be performed in different order from those described herein. Removing, adding, or rearranging system or device components, or operational aspects of the processes or methods, would be well within the skill of one of ordinary skill in the relevant art in light of this disclosure.

The operation of methods and systems for making polysilicon described herein may be under the control of automated control subsystems. Such automated control subsystems may include one or more of appropriate sensors (e.g., flow sensors, pressure sensors, temperature sensors), actuators (e.g., motors, valves, solenoids, dampers), chemical analyzers and processor-based systems which execute instructions stored in processor-readable storage media to automatically control the various components and/or flow, pressure and/or temperature of materials based at least in part on data or information from the sensors, analyzers and/or user input.

Regarding control and operation of the systems and processes, or design of the systems and devices for making polysilicon, in certain embodiments the present subject matter may be implemented via Application Specific Integrated Circuits (ASICs). However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof. Accordingly, designing the circuitry and/or writing the code for the software and or firmware would be well within the skill of one of ordinary skill in the art in light of this disclosure.

The various embodiments described above can be combined to provide further embodiments. Aspects of the embodiments can be modified, if necessary to employ concepts of various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A chemical vapor deposition reactor system comprising:
a mechanical means for substantially exposing a surface of a plurality of the dust, beads or other particulate to a gas including a first gaseous chemical species,
a means for heating the dust, beads or other particulate or the surfaces of the dust, beads or other particulate to a sufficiently high temperature such that a first gaseous chemical species brought into contact with said surfaces will chemically decompose and substantially deposit a second chemical species onto said surfaces, and
a source of a first gas selected from those chemical species which decompose on heating to one or more second chemical species, one of which is a substantially non-volatile species and prone to deposit on a hot surface in near proximity.

2. The reactor system of claim 1 wherein the first chemical species is at least one of silane gas (SiH4), trichlorosilane gas (SiHC13), or dichlorosilane gas (SiH2C12).

3. The reactor system of claim 1 wherein the mechanical means is a vibrating bed.

4. The reactor system of claim 3 wherein the vibrating bed includes at least one of an eccentric flywheel, piezoelectric transducer or sonic transducer.

5. The reactor system of claim 3 wherein the vibrating bed includes a flat pan with at least one perimeter wall extending therefrom, a bottom surface that is flat surface and is heated and the bottom and the at least one perimeter wall form a container and the dust, beads or other particulate of a second specie and are placed within the container.

6. The reactor system of claim 5 wherein a surface temperature of the heated portion of the bed is controlled to be between 100° C. and 1300° C., 100° C. and 900° C., 200° C. and 700° C., 300° C. and 600° C., or approximately 450° C.

7. The reactor system of claim 5 wherein a height of the perimeter wall is between ¼ inch and 15 inches, ½ inch and 15 inches, ½ inch and 5 inches, ½ inch and 3 inches, or is approximately 2 inches.

8. The reactor system of claim 5 wherein the bed is heated electrically.

9. The reactor system of claim 8 wherein the electric heating is performed by a resistive heating coil located beneath the surface of the pan, the resistive heating coil located within a sealed container which is insulated on all sides except for the side in direct contact with the underside of the pan and an underside of the pan forms the top side of the sealed container holding the heating coil and a pressure between the top of a containment vessel and a top surface of the pan is maintained sufficiently low as to not deform the pan.

10. The reactor system of claim 5, further comprising:
an output lock hopper including two or more isolation valves and an intermediate second containment vessel, wherein particulate overflowing from the flat pan are removed from the containment vessel through the output lock hopper.

11. The reactor system of claim 1 wherein the mechanical means includes a least one source of vibration or oscillation which produces vibration or oscillation at a frequency range between approximately 1 and 4,000 cycles per minute, between approximately 500 and 3,500 cycles per minute, between approximately 1,000 and 3,000 cycles per minute, or oscillation at a frequency of approximately 2,500 cycles per second.

12. The reactor system of claim 1 wherein the mechanical means includes a least one source of vibration or oscillation which produces vibration or oscillation at an amplitude between approximately 1/100 inch and 4 inches, approximately 1/64 inch and ¼ inch, approximately between 1/32 inch and ⅛ inch, or oscillation at an amplitude of approximately 1/64 inch.

13. The reactor system of claim 1, further comprising:
a containment vessel having an interior and an exterior, wherein at least a portion of the mechanical means includes a vibrating bed located in the interior of the containment vessel, the means for heating is at least partially located in the interior of the containment vessel and the interior of the containment vessel is filled with a gas containing the first reactant and the third non-reactive specie.

14. The reactor system of claim 13 wherein the containment vessel includes at least one wall, and the at least one wall is kept cool by means of a cooling jacket or air cooling fins located on the outside of the containment vessel and a cooling medium flows through the cooling jacket and has a temperature and a flow rate controlled so that a temperature of the gas in the interior of the containment vessel is controlled at a desired low temperature.

15. The reactor system of claim 14 wherein the bulk temperature of the gas in the interior of the containment vessel is controlled between 30 C and 500 C, between 50 C and 300 C, or 100 C, or 50 C.

16. The reactor system of claim 13 wherein the gas in the interior of the containment vessel includes the first reactant and a third non-reactive specie is added to the containment vessel, and gas comprised of first reactant, third non-reactive diluent, and one of the second species formed by the decomposition reaction is withdrawn from the containment vessel.

17. The reactor system of claim 16 wherein gas including the first reactant and third non-reactive specie is added continuously to the containment vessel, and gas comprised of first reactant, third non-reactive diluent, and one of the second species formed by the decomposition reaction is continuously withdrawn from the containment vessel.

18. The reactor system of claim 16 wherein the gas added to the containment vessel is comprised of silane gas (SiH4) and hydrogen diluent, the gas withdrawn from the containment vessel is comprised of unreacted silane gas, hydrogen diluent, and hydrogen gas formed by the decomposition reaction, and the dust and beads added to the bed are comprised of silicon.

19. The reactor system of claim 18 wherein beads are continuously harvested from the bed, and the average size of the harvested beads is controlled by adjusting a height of the perimeter wall the container.

20. The reactor system of claim 18 wherein a residual concentration of hydrogen gas entrained with the beads or incorporated into the second chemical specie comprising the beads is controlled by controlling the concentration of the hydrogen diluent in the gas added to the containment vessel and wherein the concentration of the hydrogen diluent is controlled between 0 and 90 mole percent, 0 and 80 mole percent, 0 and 50 mole percent, or 0 and 20 mole percent.

21. The reactor system of claim 16 wherein a pressure of the gas within the containment vessel is controlled between 5 psia and 300 psia, 14.7 psia and 200 psia, 30 psia and 100 psia, at 70 psia, or at the beginning of the batch reaction is controlled at 14.7 psia.

22. The reactor system of claim 13, further comprising:
an input lock hopper including two or more isolation valves and an intermediate second containment vessel coupled to the interior of the containment vessel and operable to selectively provide particulate to the interior of the containment vessel on which particulate deposition will occur.

23. The reactor system of claim 1 wherein the mechanical means for substantially exposing the surface of the plurality of beads to a gas containing a first gaseous chemical species and the means for heating the beads or the surfaces of the beads are made from metal or graphite or a combination of metal and graphite.
